(19) United States
(12) Patent Application Publication
(10) Pub. No.: US 2026/0293678 A1
(43) Pub. Date: Sep. 24, 2026

(54) Co-integration of Airbridges and 3D Integration Modules

(71) Applicant: IMEC VZW, Leuven (BE)

(72) Inventors: Vadiraj Manjunath Anathapadmanabha Rao, Leuven (BE); Jaber Derakhshandeh, Tienen (BE); Danny Wan, Leuven (BE)

(21) Appl. No.: 19/569,861

(22) Filed: Mar. 17, 2026

(30) Foreign Application Priority Data
Mar. 20, 2025 (EP) 25165026.3

(51) Int. Cl. H10W 42/00; H10N 60/01; H10P 50/00; H10W 20/00; H10W 72/00

(52) U.S. Cl. CPC H10W 42/00; H10N 60/01; H10P 50/71; H10W 20/043; H10W 72/01235

(57) ABSTRACT

A method for fabricating one or more airbridge structures and one or more 3D integration modules on a patterned metallization layer of a wafer including qubits or superconducting electronics are provided. The method includes providing the wafer with the patterned metallization layer and depositing an integrated metallization layer, either before or after providing and patterning a first resist layer. The method also includes forming one or more airbridge structures that contact the patterned metallization layer at openings in the first resist layer, wherein the one or more airbridge structures are made of a superconductive material at operating temperatures, and fabricating 3D integration modules by electroplating predefined regions of the integrated metallization layer.

### CROSS-REFERENCE TO RELATED APPLICATIONS

The present application is a non-provisional patent application claiming priority to European Patent Application No. 25165026.3, filed on Mar. 20, 2025, the contents of which are hereby incorporated by reference.

### FIELD OF THE DISCLOSURE

The present disclosure relates to the field of quantum computing, superconducting electronics, and 3D heterogeneous integration. For example, it relates to a foundry-compatible method for co-integrating airbridge structures with 3D integration modules, such as bumps, spacers, and through-silicon vias (TSVs)

### BACKGROUND

The development of large-scale quantum processors and superconducting digital logic relies on heterogeneous 3D integration for scalable (e.g., efficient) qubit architectures and logic. This approach allows for the fabrication of quantum and classical elements on separate chips, which can then be stacked and interconnected to optimize signal routing and minimize footprint. By employing through-silicon vias (TSVs) and bumps, signals can be (e.g., efficiently) distributed across multiple metallization layers, providing addressability of quantum and classical elements across the chip.

Among the components of quantum and classical processors, airbridges play a useful role in mitigating crosstalk between control lines, suppressing parasitic circuit modes that arise from disconnected ground planes, and serving as crossovers to prevent signal collisions in in-plane wiring. These functionalities preserve signal integrity and provide reliable qubit and other classical logic operations.

The fabrication of 3D integration elements for quantum computing has relied on liftoff-based processes, which are not compatible with foundry manufacturing. While liftoff techniques have been sufficient for small-scale quantum circuits, they face challenges in yield, uniformity, and scalability, making them less ideal for the fabrication of large-scale quantum processors with millions of qubits for error correction. The same holds for superconducting digital logic circuits.

Therefore, alternative methods to fabricate airbridges alongside other 3D integration elements, such as bumps, spacers, and TSVs, may address the limitations of liftoff techniques and provide a pathway towards scalability.

### SUMMARY

Example embodiments of the present disclosure provide a method for fabricating one or more airbridge structures and 3D integration modules on a patterned metallization layer of a wafer comprising qubits and/or superconducting electronics.

A method and device according to the present disclosure are provided herein.

In a first example embodiment of the present disclosure, a method is provided. The method is for fabricating one or more airbridge structures and one or more 3D integration modules on a patterned metallization layer of a wafer comprising qubits and/or superconducting electronics. The method comprises providing the wafer with the patterned metallization layer. An integrated metallization layer is deposited on the wafer, either before or after providing and patterning a first resist layer. One or more airbridge structures are formed on the patterned metallization layer. These one or more airbridge structures may contact the patterned metallization layer at openings in the first resist layer. The one or more airbridge structures are superconductive at operating temperatures. The one or more airbridge structures contact the patterned metallization layer at openings in the first resist layer. At such an opening, there is a direct contact between a concerned airbridge structure and the integrated metallization layer, and a direct contact between the integrated metallization layer and the patterned metallization layer. The integrated metallization layer between the one or more airbridge structures and the patterned metallization layer is superconductive, at operating temperatures, at least due to the proximity effect. Alternatively, the integrated metallization layer provides a galvanic contact between the one or more airbridge structures and the patterned metallization layer with a resistance smaller than a predefined threshold at operating temperatures, for preserving qubit coherence and/or maintaining superconductivity in superconductive electronics. In example embodiments of the present disclosure, the qubit coherence is preserved by minimizing resistive losses. In example embodiments of the present disclosure, the galvanic contact may have a resistance, at operating temperatures, smaller than 1000 nOhm, or even smaller than 500 nOhm, or even smaller than 100 nOhm, or even smaller than 10 nOhm, or even smaller than 5 nOhm per galvanic contact. The method further comprises fabricating 3D integration modules by electroplating predefined regions of the integrated metallization layer.

It is an improvement of example embodiments of the present disclosure that the method not only provides making airbridges, but also provides (e.g., enables) making 3D integration modules by (e.g., performing) electroplating. It is an improvement of example embodiments of the present disclosure that the integrated metallization layer provides (e.g., enables) efficient integration of airbridge structures and subsequent electroplating steps.

In example embodiments of the present disclosure, the integrated metallization layer can be used for electroplating the 3D integration modules and as contact between the airbridge structures and the patterned metallization layer.

In example embodiments of the present disclosure, the method provides superconductivity at operating temperatures, preserving qubit coherence by minimizing resistive losses.

Example embodiments of the present disclosure provide a process tailored for large-scale quantum and superconducting digital processors, leveraging a foundry-compatible approach for fabricating airbridge structures and 3D integration modules, such as bumps and spacers. The use of an integrated metallization layer, combining a barrier layer and a seed layer, simplifies the fabrication process and improves (e.g., enhances) its versatility.

Furthermore, the compatibility with electroplating and the elimination of liftoff techniques improve manufacturing uniformity, yield, and scalability.

In example embodiments of the present disclosure, the superconductive material comprises Al, or Ta, or Nb, or TiN.

In example embodiments of the present disclosure, the integrated metallization layer comprises a barrier layer and a seed layer.

In example embodiments of the present disclosure, the barrier material is superconducting (e.g., TiN, TaN, NbTiN, Ta, Nb). It serves as a diffusion barrier for the seed material. In example embodiments of the present disclosure, it also serves as a protection layer for the quantum circuit material during 3DI processing.

In example embodiments of the present disclosure, the material of the seed layer, for example, may be Cu or Ru. Ru provides (e.g., enables) different spacer materials other than Cu.

In example embodiments of the present disclosure, the integrated metallization layer may be made of one layer made of a material which is superconductive at the operating temperature and which is also conductive at room temperature for (e.g., efficient) electroplating.

In example embodiments of the present disclosure, the method comprises locally etching the seed layer using a same mask as for patterning the first resist layer.

In example embodiments of the present disclosure patterning the first resist layer comprises a reflow step for making tapered sidewalls. This is the case for organic resist. Alternatively, when a hard mask is used, tapered sidewalls may be obtained by controlling the etch parameters of the mask.

It is an improvement of example embodiments of the present disclosure that the tapered sidewalls provide conformal coverage (e.g., after subsequent metal deposition).

In example embodiments of the present disclosure, the method comprises depositing the integrated metallization layer before providing and patterning the first resist layer. The one or more airbridge structures are formed by depositing the superconductive material using thin-film deposition. The deposited superconductive material is patterned and etched using a second resist layer to provide (e.g., define) regions for the one or more airbridge structures, thereby obtaining the one or more airbridge structures. The second resist layer and the first resist layer are then removed. After fabricating the 3D integration modules, the integrated metallization layer is etched to release the one or more airbridge structures and the 3D integration modules.

In example embodiments of the present disclosure, the thin-film deposition may be by PVD, CVD, or ALD.

In example embodiments of the present disclosure, the method comprises depositing the integrated metallization layer after providing and patterning the first resist layer. The one or more airbridge structures are formed by applying a second resist layer to provide (e.g., define) regions for the one or more airbridge structures. The superconductive material of the one or more airbridge structures is electroplated in the regions provided (e.g., defined) by the second resist layer. After fabricating the 3D integration modules, a protection resist is provided to protect the 3D integration modules and the one or more airbridge structures. The integrated metallization layer is then etched, and the protection resist material is removed to release the one or more airbridge structures and the 3D integration modules.

It is an improvement of example embodiments of the present disclosure that the method incorporates electroplating to form the superconductive airbridge structures, providing (e.g., enabling) the deposition of (e.g., thick, robust) materials with (e.g., well-defined) geometries (e.g., that are essential) for shielding, crosstalk mitigation, and mechanical stability. Rhenium (Re), Aluminum (Al), and Ruthenium (Ru) are examples of superconducting materials that can be plated.

In example embodiments of the present disclosure, the method comprises depositing the integrated metallization layer after providing and patterning the first resist layer. The one or more airbridge structures are formed by applying a second resist layer to provide (e.g., define) regions for the one or more airbridge structures. A metal hardmask is electroplated in the regions provided (e.g., defined) by the second resist layer. After fabricating the 3D integration modules, a protection resist is provided to protect the 3D integration modules while keeping the metal hardmask exposed. The integrated metallization layer is etched except for the regions of the protection resist layer and the regions where the metal hardmask serves as protection. Any remaining metal hardmask is then removed using a resist mask which exposes only the hard mask, followed by the removal of this resist mask to release the one or more airbridge structures.

It is an improvement of example embodiments of the present disclosure that the airbridge structure is fully superconductive based on its material composition, independent of the proximity effect.

In example embodiments of the present disclosure, the one or more airbridge structures have a length between contacts on the patterned metallization layer between 20 µm (micrometers) and 100 µm.

In example embodiments of the present disclosure, the one or more airbridge structures have a width of more than 10 µm.

It is an improvement of example embodiments of the present disclosure that the airbridge structures can also be used for shielding. They can, for example, have widths of several hundreds of micrometers.

In example embodiments of the present disclosure, the one or more airbridge structures are formed using electroplating and have a width of more than hundred micrometers.

It is an improvement of example embodiments of the present disclosure that the airbridge structures formed using electroplating can achieve widths of more than hundred micrometers, or even up to several hundred micrometers and more, providing improved (e.g., enhanced) functionality such as electromagnetic shielding and improved mechanical stability. This increased width allows the airbridges to not only serve as signal crossovers but also as effective shields against crosstalk and spurious modes, which are useful (e.g., critical) for maintaining signal integrity in quantum processors. Furthermore, the use of electroplating provides scalability for fabricating such wide structures, making this method (e.g., particularly) suitable for industrial-scale quantum processor or superconducting digital logic processor manufacturing, where robust and multifunctional components are useful (e.g., essential). It is an improvement of example embodiments of the present disclosure that the avoidance of liftoff makes electroplating more compatible with foundry manufacturing.

It is an improvement of example embodiments of the present disclosure that plating may create (e.g., thick mechanically) robust structures.

In example embodiments of the present disclosure, the electroplating process used for fabricating the 3D integration modules includes forming bumps made of superconducting material to provide (e.g., enable) superconducting connections between bonded wafers. The bumps may, for example, be made of Indium or Indium-Tin alloys.

In example embodiments of the present disclosure, the electroplating process used for fabricating the 3D integration modules includes forming spacers. Spacer materials can be composed of copper (Cu), ruthenium (Ru), or other suitable metals.

In a second example embodiment of the present disclosure, a method for forming a quantum processor is provided.

The method comprises fabricating airbridge structures and 3D integration modules on a patterned metallization layer of a wafer comprising qubits and/or superconducting electronics, using a method according to the first example embodiment of the present disclosure. The method comprises bonding the wafer to an additional wafer, comprising 3D integration modules, using the 3D integration modules of both wafers to establish electrical and mechanical connections.

In example embodiments of the present disclosure, at least one of the airbridge structures is configured to mitigate crosstalk and spurious modes in the quantum processor.

Example embodiments of the present disclosure are set out in the accompanying independent and dependent claims. Features from the dependent claims may be combined with features of the independent claims and with features of other dependent claims as appropriate and not merely as explicitly set out in the claims.

These and other example embodiments of the present disclosure will be apparent from and elucidated with reference to the embodiment(s) described hereinafter.

### BRIEF DESCRIPTION OF THE FIGURES

The above, as well as additional, features will be better understood through the following illustrative and non-limiting detailed description of example embodiments, with reference to the appended drawings.

FIG. 1 illustrates schematic representations of intermediate stacks obtained during the method steps of an example embodiment of the present disclosure, wherein the integrated metallization layer is deposited before providing and patterning the first resist layer.

FIG. 2 illustrates schematic representations of intermediate stacks obtained during the method steps of an example of the present disclosure, wherein the integrated metallization layer after providing and patterning the first resist layer.

FIG. 3 illustrates schematic representations of intermediate stacks obtained during the method steps of an example embodiment of the present disclosure, wherein a metal hardmask is provided by electroplating.

Any reference signs in the claims shall not be construed as limiting the scope.

In the different drawings, the same reference signs refer to the same or analogous elements.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

The present disclosure will be described with respect to example embodiments and with reference to certain drawings but the present disclosure is not limited thereto but only by the claims. The drawings described are only schematic and are non-limiting. In the drawings, the size of some of the elements may be exaggerated and not drawn on scale for illustrative purposes. The dimensions and the relative dimensions may not correspond to actual reductions to practice of the present disclosure.

The terms first, second and the like in the description and in the claims, are used for distinguishing between similar elements and not necessarily for describing a sequence, either temporally, spatially, in ranking, or in any other manner. The terms used are interchangeable under appropriate circumstances and that the example embodiments of the present disclosure described herein are capable of operation in other sequences than described or illustrated herein.

Moreover, the terms top, under, and the like in the description and the claims are used for descriptive purposes and not necessarily for describing relative positions. The terms so used are interchangeable under appropriate circumstances and that the embodiments of the present disclosure described herein are capable of operation in other orientations than described or illustrated herein.

The term “comprising”, used in the claims, should not be interpreted as being restricted to the elements and/or steps (e.g., means) listed thereafter; it does not exclude other elements or steps. It is thus to be interpreted as providing (e.g., specifying) the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It provides (e.g., means) that with respect to the present disclosure, the (e.g., only) relevant components of the device are A and B.

Reference throughout this specification to “one embodiment” or “an embodiment” or “an example embodiment” provides (e.g., means) that a particular feature, structure, or characteristic described in connection with the embodiment is included in at least one embodiment of the present disclosure. Thus, appearances of the phrases “in one embodiment” or “in an embodiment” or “in an example embodiment” throughout the present disclosure (e.g., this specification) may not necessarily (e.g., all) refer to the same embodiment, but, on the other hand, may refer to the same embodiment. Furthermore, example (e.g., particular) features, structures, or characteristics may be combined in any suitable manner, as would be apparent to one of ordinary skill in the art from this disclosure, in one or more embodiments.

Similarly, it should be appreciated that in the description of example embodiments of the present disclosure, various features of the present disclosure are sometimes grouped together in a single embodiment, figure, or description thereof for the purpose of streamlining the disclosure and aiding in the understanding of one or more of the various example embodiments. This method of disclosure, however, is not to be interpreted as reflecting an intention that the claimed present disclosure uses more features than are (e.g., expressly) recited in each claim. Rather, as the following claims reflect, example embodiments lie in less than all features of a single foregoing disclosed embodiment. Thus, the claims following the detailed description are hereby (e.g., expressly) incorporated into this detailed description, with each claim standing on its own as a separate embodiment of this present disclosure.

Furthermore, while some example embodiments described herein include some but not other features included in other example embodiments, combinations of features of different example embodiments are meant to be within the scope of the present disclosure, and form different example embodiments, as would be understood by those in the art. For example, in the following claims, any of the claimed embodiments can be used in any combination.

In the description provided herein, numerous specific details are set forth. However, example embodiments of the present disclosure may be practiced without these specific details. In other instances, well-known methods, structures, and techniques may not be shown in detail in order not to obscure an understanding of this description.

In example embodiments of the present disclosure, reference to “airbridge structures” references conductive bridges that are elevated above the substrate surface and span over features or gaps of the wafer comprising qubits and/or superconducting electronics. These airbridge structures are made of a material that is superconductive at operating temperatures.

In example embodiments of the present disclosure, reference to “3D integration modules” references structures formed on a wafer that provide (e.g., enable) vertical electrical and mechanical connections between stacked wafers or layers in a three-dimensional configuration. These modules are fabricated by (e.g., performing) electroplating on designated regions of the integrated metallization layer. Examples of 3D integration modules include electroplated pillars or bumps made of superconducting material that facilitate inter-wafer connectivity in quantum processors.

In example embodiments of the present disclosure, reference to a “patterned metallization layer” references a layer of conductive material on a wafer comprising qubits and/or superconducting electronics that has been selectively etched or deposited to provide (e.g., define) the qubit circuitry and/or superconducting electronics circuitry and associated components. This patterning creates the structures (e.g., necessary) for qubit operation, such as resonators, control lines, and coupling elements. Examples include superconducting layers patterned using photolithography and etching techniques to form superconducting qubits and related circuitry.

In example embodiments of the present disclosure, reference to a “wafer comprising qubits and/or superconducting electronics” references a semiconductor or insulating substrate on which qubit devices and/or superconducting electronics and associated circuitry are fabricated for use in quantum computing applications. The wafer may serve as the foundational platform for constructing a quantum processor. Examples of wafers include silicon, sapphire, or silicon-on-insulator (SOI) wafers used for implementing superconducting or semiconductor qubits and/or superconducting electronics.

In example embodiments of the present disclosure, reference to an “integrated metallization layer” references a conductive layer deposited over the wafer comprising qubits and/or superconducting electronics, that serves multiple functions, including acting as a seed layer for electroplating and providing electrical connectivity between various structures. This layer may comprise one or more sub-layers, such as barrier and seed layers, to improve (e.g., enhance) adhesion and conductivity.

In example embodiments of the present disclosure, reference to a “resist layer” references a layer of photosensitive or electron-sensitive material applied to the wafer surface that can be patterned using lithographic techniques to provide (e.g., define) specific areas for processing. The resist layer serves as a mask during etching, deposition, or electroplating processes. Examples include positive or negative photoresists used in ultraviolet lithography to create patterns for subsequent fabrication steps. In example embodiments of the present disclosure, a “resist mask” can also be a hard mask that can selectively be removed with respect to other materials on the wafer after its purpose is served.

In example embodiments of the present disclosure, the patterned metallization layer of the wafer comprising qubits and/or superconducting electronics, are for a quantum processor. In example embodiments of the present disclosure, reference to a “superconductive material at operating temperatures” references a material that exhibits superconductivity—zero electrical resistance—at the temperatures at which the quantum processor of qubit devices operate. These operating temperatures are typically cryogenic. Examples of such materials include aluminium, tantalum, niobium, or niobium nitride, which become superconducting below their critical temperatures relevant for quantum computing applications.

In example embodiments of the present disclosure, reference to “operating temperatures” references the temperatures at which the quantum processor or qubit devices are designed to function effectively, often having (e.g., requiring) cryogenic conditions to maintain superconductivity. These operating temperatures may, for example, be below 4 Kelvin.

In example embodiments of the present disclosure, reference to the “proximity effect” references the phenomenon where a superconducting property is induced in a non-superconducting material when it is in close contact with a superconducting material due to the penetration of Cooper pairs into the non-superconducting region. This effect allows the integrated metallization layer material between the airbridge structures and the patterned metallization layer to become superconductive.

In example embodiments of the present disclosure, reference to the “reflow step” references a process wherein the resist layer is heated to a temperature (e.g., sufficient) to cause the resist material to soften and flow, resulting in the smoothening of resist profiles or the formation of tapered sidewalls. This modification aids in subsequent deposition processes by improving material coverage over the resist features. An example is heating a photoresist above its glass transition temperature to achieve tapered sidewalls for better metal step coverage.

In example embodiments of the present disclosure, reference to “electroplating” references a method of depositing a metal layer onto a conductive surface by passing an electrical current through a solution containing metal ions, causing them to reduce and form a solid metal coating on the cathode surface. This technique may be used to fabricate features such as the 3D integration modules and airbridge structures.

In example embodiments of the present disclosure, reference to a “quantum processor” references a computing device that utilizes the principles of quantum mechanics, such as superposition and entanglement, to perform computations using quantum bits (qubits). The processor comprises qubit devices and associated circuitry fabricated on a wafer comprising qubits and/or superconducting electronics.

In example embodiments of the present disclosure, reference to a “bump” references a raised metallic feature formed on a wafer surface, which may (e.g., typically) be used to establish electrical and mechanical connections between bonded wafers in flip-chip or wafer-level packaging.

In example embodiments of the present disclosure, reference to a “spacer,” references a raised structure formed on a wafer surface, which may (e.g., typically) be used as a mechanical stop during bonding. The spacer helps to (e.g., accurately) control the gap between bonded chips, providing (e.g., ensuring) precise alignment and mechanical stability in 3D integration processes. In (e.g., all) example embodiments of the present disclosure, the spacer is made of material which can be electroplated. In example embodiments of the present disclosure, the spacer is made of metallic material. It is an improvement of example embodiments of the present disclosure that a strong spacer is obtained which resists deformation.

In example embodiments of the present disclosure, reference to a “seed layer” references a thin conductive film that provides a nucleation site for subsequent metal deposition processes, such as electroplating.

In example embodiments of the present disclosure, reference to a “barrier layer” references a thin film between the substrate and the seed layer to prevent interdiffusion of materials and improve (e.g., enhance) adhesion. The barrier layer provides the integrity of the metallization system during subsequent processing steps. In example embodiments of the present disclosure, the barrier layer protects the patterned metallization layer during the full process. In example embodiments of the present disclosure, the barrier layer is etched away while preserving the patterned metallization layer.

A first example embodiment of the present disclosure relates to a method (100) for fabricating one or more airbridge structures (240) and 3D integration modules (251, 252) on a patterned metallization layer (211) of a wafer (210) comprising qubits and/or superconducting electronics. The patterned metallization layer may for example comprise Aluminum (Al), Tantalum (Ta), Niobium (Nb), Titanium Nitride (TiN).

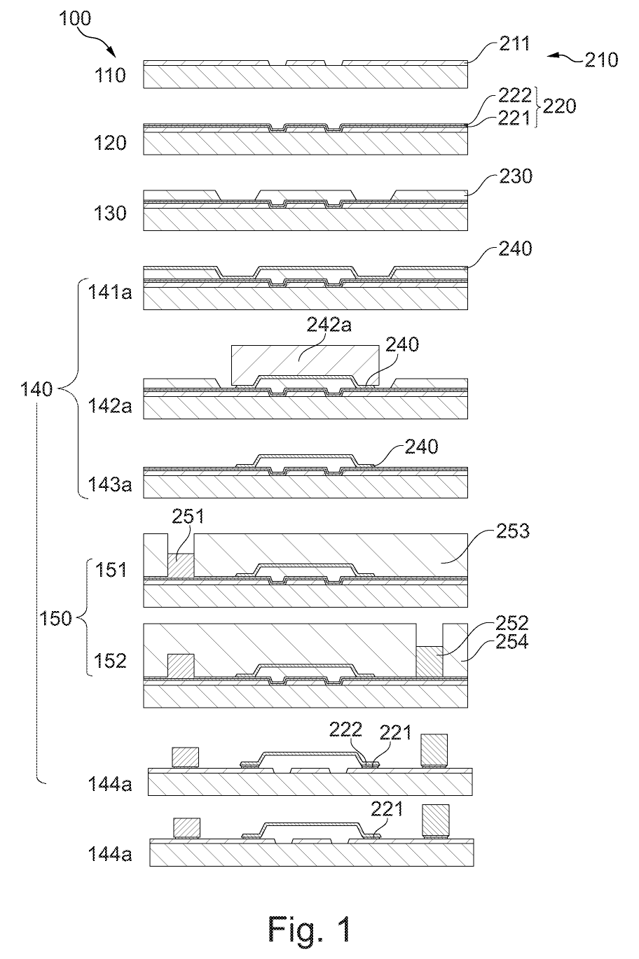

Examples of such methods are illustrated in FIGS. 1, 2, and 3.

The method (100) comprises providing (110) the wafer (210) with the patterned metallization layer (211). As illustrated in FIGS. 1, 2, and 3, the wafer (210) comprising qubits and/or superconducting electronics is shown as a rectangular block, representing a substrate, with the patterned metallization layer (211) as a (e.g., thin) layer on top of it.

The method further comprises depositing (120) an integrated metallization layer (220) on the wafer, either before or after providing and patterning (130) a first resist layer (230). One or more airbridge structures (240) are formed (140) on the patterned metallization layer (211). The one or more airbridge structures (240) are contacting the patterned metallization layer (211) at openings in the first resist layer (230). These openings are obtained when patterning the first resist layer (230). The airbridge structures (240) comprise superconductive material at operating temperatures. The integrated metallization layer (220) between the airbridge structures (240) and the patterned metallization layer (211) is superconductive, at operating temperatures, at least due to the proximity effect, or the integrated metallization layer provides a galvanic contact between the airbridge structures (240) and the patterned metallization layer (211) with a resistance smaller than a predefined threshold, at operating temperatures, for preserving qubit coherence and/or maintaining superconductivity in superconductive electronics by minimizing resistive losses.

The method further comprises fabricating (150) one or more 3D integration modules (251, 252) by electroplating predefined regions of the integrated metallization layer (220). Resist (253, 254) may be provided for providing (e.g., defining) the regions where the 3D integration modules (251, 252) are electroplated. This resist is removed afterwards.

In example embodiments of the present disclosure, the integrated metallization layer (220) comprises a barrier layer (221) and a seed layer (222). This is illustrated in FIGS. 1-3. In example embodiments of the present disclosure, the barrier material is superconducting, comprising materials such as titanium nitride (TiN), tantalum nitride (TaN), or niobium titanium nitride (NbTiN). It functions as a diffusion barrier to prevent the migration of the seed material (e.g. Cu, Ru). Additionally, it acts as a protective layer for the quantum circuit material during 3D integration processing. In example embodiments of the present disclosure, the barrier layer is used for adhesion purposes for the seed layer.

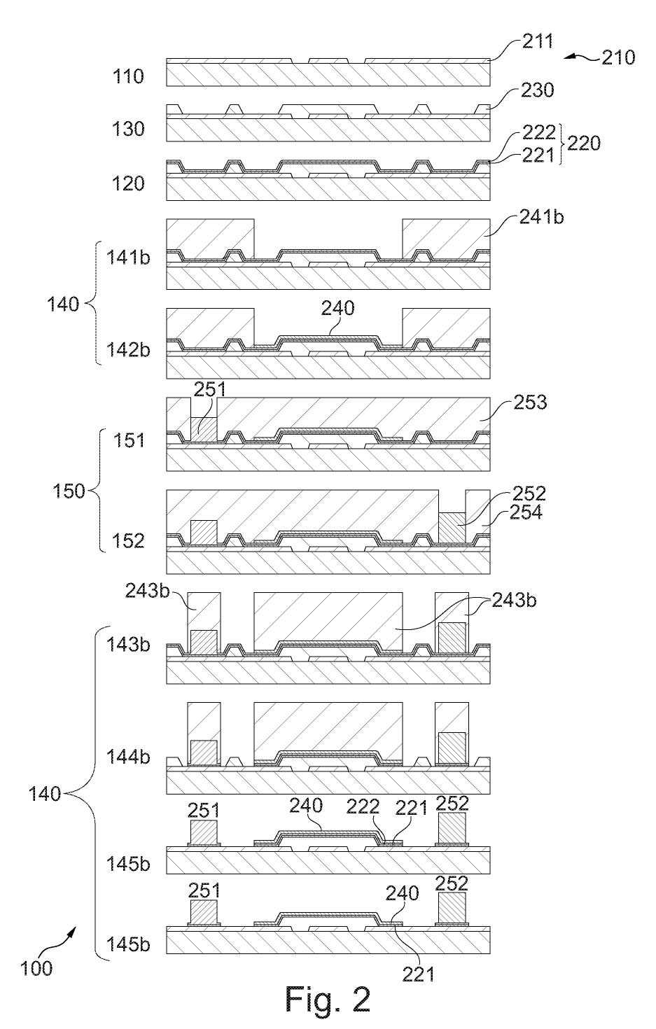

In example embodiments of the present disclosure, the method comprising locally etching the seed layer (222) using a same mask as for patterning (130) the first resist layer (230). The result thereof is shown in the bottom stack of FIGS. 1 and 2 which (e.g., only) show the barrier layer (221) between the airbridge structure (240) and the patterned metallization layer (211).

In example embodiments of the present disclosure, patterning (130) the first resist layer comprises a reflow step for making tapered sidewalls.

In example embodiments of the present disclosure, the integrated metallization layer (220) is deposited before providing and patterning the first resist layer (230). An example of such a method is illustrated in FIG. 1.

In example embodiments of the present disclosure, the first resist layer can be composed of an organic resist or a hardmask material.

The one or more airbridge structures (240) are formed (140) by depositing (141a) the superconductive material using thin-film deposition. In example embodiments of the present disclosure, conformal coverage is provided.

The deposited superconductive material is then patterned and etched (142a), using a second resist layer (242a) to provide (e.g., define) regions for the one or more airbridge structures, thereby obtaining the one or more airbridge structures (240). The etching (142a) of the airbridge metal may be done by wet or dry etching.

The second resist layer (242a) and the first resist layer (230) are subsequently removed (143a) by selective removal with respect to other materials used so far.

The 3D integration modules (251, 252) are fabricated (150).

In example embodiments of the present disclosure, a spacer lithography mask (253) is provided and patterned, followed by the electroplating of the spacer material (251). Thus, co-integration of airbridges and spacers is achieved. The spacer material can be copper (Cu) or any other electroplatable superconductor, such as ruthenium (Ru), rhenium (Re), or aluminum (Al). In example embodiments of the present disclosure, the selection of the seed layer (222) is impacted (e.g., influenced) by the choice of spacer material.

In example embodiments of the present disclosure, a bump lithography mask (254) is patterned, followed by the electroplating of the bump material (252). Thus, co-integration of airbridges and bumps is achieved. The bump material can be indium (In), tin-indium (SnIn) alloy, or any other suitable superconductor. In example embodiments of the present disclosure the selection of the seed layer (222) is impacted (e.g., influenced) by the choice of bump material.

After providing the 3D integration modules (spacer, bump), the lithography mask is removed.

In a following step, the integrated metallization layer (220) is etched (144a) to release the one or more airbridge structures (240) and the 3D integration modules (251, 252). The etching may be wet or dry. In example embodiments of the present disclosure, the etching is selective to (e.g., all) the other materials present.

In the example embodiment illustrated in FIG. 2, the method (100) comprises depositing the integrated metallization layer (220) after providing and patterning the first resist layer (230). In example embodiments of the present disclosure, the resist layer (230) can be either an organic resist or a hardmask. In example embodiments of the present disclosure, the mask undergoes a reflow process to create tapered sidewalls. In example embodiments of the present disclosure, the first mask layer is designed so that the open areas on the substrate correspond to the regions where electroplating may be performed.

In example embodiments of the present disclosure, the integrated metallization layer may consist of a barrier layer and a seed layer. The barrier material is superconducting and can include TiN, TaN, or NbTiN. It functions as a diffusion barrier for the seed material (e.g., Cu or Ru) and also serves as a protective layer for the quantum circuit material during 3D integration processing and also may serve to improve (e.g., enhance) the adhesion of the seed layer. The seed material can be Cu or Ru, depending on the processing specifications (e.g., requirements). Alternatively, the integrated metallization layer can be composed of a single superconducting material that fulfills both the barrier and seed layer functions.

The one or more airbridge structures (240) are formed by applying (141b) a second resist layer (241b) to provide (e.g., define) the regions for the one or more airbridge structures (240). The second resist layer can be an organic resist or a hardmask. In example embodiments of the present disclosure, local seed (222) etch may be done using the second resist layer (241b). The resulting stack, without seed layer, is illustrated in the bottom drawing of FIG. 2

The superconductive material of the one or more airbridge structures (240) is electroplated (142b) within the regions provided (e.g., defined) by the second resist layer (241b). In example embodiments of the present disclosure, the airbridge metal is a superconductor which can be electroplated, such as Ru, Re, Al.

In example embodiments of the present disclosure, a spacer lithography mask (253) is provided and patterned, followed by the electroplating of the spacer material (251). Thus, co-integration of airbridges and spacers is achieved. The spacer material can be Cu or any other electroplatable superconductor, such as Ru, Re, or Al. In example embodiments of the present disclosure, the selection of the seed layer (222) is impacted (e.g., influenced) by the choice of spacer material.

In example embodiments of the present disclosure, a bump lithography mask (254) is patterned, followed by the electroplating of the bump material (252). Thus, co-integration of airbridges and bumps is achieved. The bump material can be In, SnIn alloy, or any other suitable superconductor. In example embodiments of the present disclosure, the selection of the seed layer (222) is impacted (e.g., influenced) by the choice of bump material.

A local seed etch can be performed using the bump lithography mask prior to plating the bumps.

After fabricating (150) the 3D integration modules (251, 252), a protection resist (243b) is applied (143b) to protect the 3D integration modules (251, 252) and the one or more airbridge structures (240). These critical structures are protected during the subsequent etching of the integrated metallization layer, providing (e.g., ensuring) process uniformity.

The integrated metallization layer (220) is then etched (144b), and the resist material is removed (145b) to release the one or more airbridge structures (240) and the 3D integration modules (251, 252). The etching may be wet or dry etching. In example embodiments of the present disclosure, the etching is selective to (e.g., all) the other materials present.

Next the protection resist (243b) is removed. Depending on the whether or not a seed etch is performed, a stack with seed layer (222) underneath the airbridge (240) is obtained (second-to-last stack), or a stack without seed layer underneath the airbridge (240) is obtained (bottom stack).

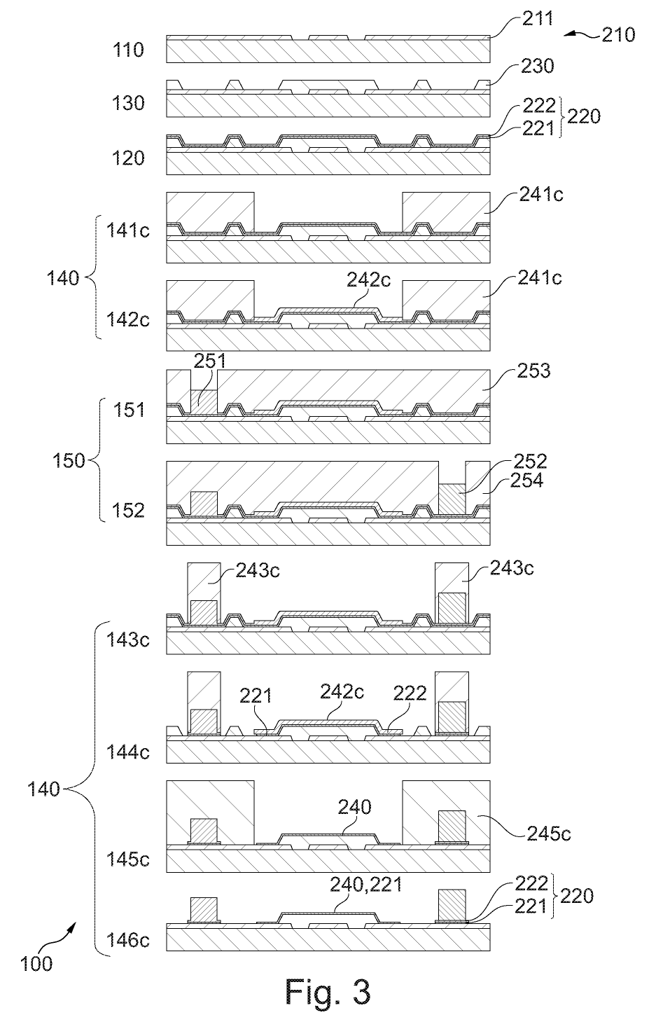

In the example embodiment illustrated in FIG. 3 the method (100) comprises depositing the integrated metallization layer (220) after providing and patterning the first resist layer (230). In example embodiments of the present disclosure, the resist layer (230) can be either an organic resist or a hardmask. In example embodiments of the present disclosure, the mask undergoes a reflow process to create tapered sidewalls. In example embodiments of the present disclosure, the first mask layer is designed so that the open areas on the substrate correspond to the regions where electroplating may be performed.

In example embodiments of the present disclosure, the integrated metallization layer may consist of a barrier layer and a seed layer. The barrier material is superconducting and can include TiN, TaN, or NbTiN. It functions as a diffusion barrier for the seed material (e.g. Cu) and also serves as a protective layer for the quantum circuit material during 3D integration processing. In example embodiments of the present disclosure the seed material is Cu, and also may serve to improve (e.g., enhance) the adhesion of the seed layer. Alternatively, the integrated metallization layer can be composed of a single superconducting material that fulfills both the barrier and seed layer functions.

The one or more airbridge structures (240) are formed by applying (141c) a second resist layer (241c) to provide (e.g., define) regions for the one or more airbridge structures. The second resist layer can be an organic resist or a hardmask.

A metal hardmask (242c) is electroplated (142c) in the regions provided (e.g., defined) by the second resist layer (241c). In example embodiments of the present disclosure, the metal hardmask is made of Cu. The Cu airbridge serves as a hardmask for the subsequent formation of the actual airbridge, which may be superconducting in operating conditions.

In example embodiments of the present disclosure, a spacer lithography mask (253) is provided and patterned, followed by the electroplating of the spacer material (251). Thus, co-integration of airbridges and spacers may be achieved. The spacer material can be Cu or any other electroplatable superconductor, such as Ru, Re, or Al. In example embodiments of the present disclosure, the selection of the seed layer (222) is impacted (e.g., influenced) by the choice of spacer material.

In example embodiments of the present disclosure, a bump lithography mask (254) is patterned, followed by the electroplating of the bump material (252). Thus, co-integration of airbridges and bumps may be achieved. The bump material can be In, SnIn alloy, or any other suitable superconductor. In example embodiments of the present disclosure, the selection of the seed layer (222) is impacted (e.g., influenced) by the choice of bump material.

A local seed etch can be performed using the bump lithography mask prior to plating the bumps.

After fabricating (150) the 3D integration modules (251, 252), a protection resist (243c) is applied (143c) to protect the 3D integration modules (251, 252) while keeping the metal hardmask exposed.

The integrated metallization layer (220) is then etched (144c) except in the regions where the metal hardmask (242c) serves as a protective layer, and in the regions where the protection resist (243c) serves as a protective layer. The etching may be wet or dry etching and is selective to (e.g., all) the other materials present. The etching may also remove part of the hardmask (242c) above the airbridge (240). Since the hardmask (242c) is thicker than the seed layer (222), it may survive the etch step.

In the next step, a resist (245c) is applied leaving the remaining metal hardmask (242c) exposed. Any remaining metal hardmask (242c) and seed layer (222) is subsequently removed (145c), and the etching is done selective to the barrier material (221), providing (e.g., ensuring) that the remaining superconducting barrier material is preserved.

In a next step, the resist (245c) is removed (146c) to release the one or more airbridge structures (240) and superconducting bridges are obtained.

In example embodiments of the present disclosure, the airbridge structures have a length between contacts on the patterned metallization layer (211) between 20 µm and 100 µm. The length is measured as the shorted distance between the contacts.

In example embodiments of the present disclosure the airbridge structures (240) have a width of more than 10 µm.

The width of the airbridge structure is measured orthogonal to the length (between contacts on the patterned metallization layer) and parallel with the surface of the patterned metallization layer.

In example embodiments of the present disclosure, the airbridge structures (240) are formed (130) using electroplating and exhibit a width of more than a hundred micrometers.

In example embodiments of the present disclosure, the electroplating process used for fabricating the 3D integration modules (251, 252) includes forming bumps made of superconducting material to provide (e.g., enable) superconducting connections between bonded wafers.

A second example embodiment of the present disclosure relates to a method for forming a quantum processor. The method comprises fabricating airbridge structures (240) and 3D integration modules (251, 252) on a patterned metallization layer (211) of a wafer comprising qubits and/or superconducting electronics using the fabrication method (100) described in the first example embodiment of the present disclosure. The wafer is then bonded to an additional wafer that also comprises 3D integration modules, with the 3D integration modules of both wafers establishing electrical and mechanical connections. This provides (e.g., enables) the creation of multi-layer quantum processors with improved (e.g., enhanced) interconnectivity and optimized signal routing. In example embodiments of the present disclosure, at least one of the airbridge structures is configured to mitigate crosstalk and suppress spurious modes in the quantum processor, further improving the (e.g., overall) performance and scalability of the quantum computing system.

It is an improvement of example embodiments of the present disclosure that an integration technique is provided that provides scalability while preserving quantum coherence.

It is an improvement of example embodiments of the present disclosure that it provides (e.g., enables) full 3D heterogeneous integration which is useful (e.g., necessary) for large-scale quantum computing by incorporating bumps, spacers, and through-silicon-via (TSV) modules, which facilitate signal routing and improve qubit addressability in the third dimension.

Airbridges play a useful (e.g., critical) role in mitigating spurious circuit modes and crosstalk in qubit control and readout lines while also providing (e.g., enabling) signal crossovers for in-plane wiring.

It is an improvement of example embodiments of the present disclosure that a qubit-compatible process flow is provided that co-integrates airbridges with 3D integration modules, providing (e.g., ensuring) the improvements of both.

In example embodiments of the present disclosure, the method provides (e.g., enables) the co-integration of airbridges and 3D integration modules within a 300mm foundry-compatible process. The airbridge fabrication process is designed to be compatible with electroplating steps used for 3D integration, providing (e.g., ensuring) seamless integration with bumps, spacers, and through-silicon vias. Unlike methods that rely on lift-off techniques, which lack scalability and result in high process variability, the example embodiments of the present disclosure provide a (e.g., robust and manufacturable) solution suitable for large-scale quantum processor fabrication.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A method for fabricating one or more airbridge structures and one or more 3D integration modules on a patterned metallization layer of a wafer comprising qubits or superconducting electronics, the method comprising:
providing the wafer with the patterned metallization layer;
depositing an integrated metallization layer on the wafer, before or after providing and patterning a first resist layer;
forming one or more airbridge structures, wherein:
the one or more airbridge structures contact the patterned metallization layer at openings in the first resist layer;
the one or more airbridge structures are superconductive at operating temperatures;
the integrated metallization layer is between the one or more airbridge structures; and
the patterned metallization layer is superconductive at operating temperatures, at least due to a proximity effect, or provides a galvanic contact between the one or more airbridge structures and the patterned metallization layer with a resistance smaller than a predefined threshold at operating temperatures, for preserving qubit coherence or maintaining superconductivity in superconductive electronics; and
fabricating one or more 3D integration modules by electroplating predefined regions of the integrated metallization layer.

2. The method according to claim 1, wherein the integrated metallization layer comprises a barrier layer and a seed layer.

3. The method according to claim 2, the method comprising patterning the first resist layer with a first mask and locally etching the seed layer using the first mask.

4. The method according to claim 1, wherein patterning the first resist layer comprises reflowing for making tapered sidewalls.

5. The method according to claim 1, wherein the integrated metallization layer is deposited before providing and patterning the first resist layer.

6. The method according to claim 5, wherein the one or more airbridge structures are formed by:
depositing a superconductive material using thin-film deposition; and
patterning and etching the deposited superconductive material, using a second resist layer to provide regions for the one or more airbridge structures.

7. The method according to claim 6, wherein the one or more airbridge structures are formed by removing the second resist layer and the first resist layer.

8. The method according to claim 7, wherein the one or more airbridge structures are formed by, after fabricating the 3D integration modules, etching the integrated metallization layer to release the one or more airbridge structures and the 3D integration modules.

9. The method according to claim 1, wherein the integrated metallization layer is deposited after providing and patterning the first resist layer, and wherein the one or more airbridge structures are formed by:
applying a second resist layer to provide regions for the one or more airbridge structures; and
electroplating a superconductive material of the one or more airbridge structures in the regions provided by the second resist layer.

10. The method according to claim 9, wherein the one or more airbridge structures are formed by, after fabricating the 3D integration modules, providing a protection resist for protecting the 3D integration modules and the one or more airbridge structures.

11. The method according to claim 10, wherein the one or more airbridge structures are formed by:
etching the integrated metallization layer; and
removing resist material to release the one or more airbridge structures and the 3D integration modules.

12. The method according to claim 1, wherein the integrated metallization layer is deposited after providing and patterning the first resist layer and wherein the one or more airbridge structures are formed by:
applying a second resist layer to provide regions for the one or more airbridge structures; and
electroplating a metal hardmask in the regions provided by the second resist layer.

13. The method according to claim 12, wherein the one or more airbridge structures are formed by, after fabricating the 3D integration modules, providing a protection resist for protecting the 3D integration modules while the metal hardmask is exposed.

14. The method according to claim 13, wherein the one or more airbridge structures are formed by:
etching the integrated metallization layer except for the regions where the metal hardmask serves as protection and in regions where the protection resist serves as a protective layer; and
removing remaining metal hardmask and removing resist material to release the one or more airbridge structures.

15. The method according to claim 1, wherein the one or more airbridge structures have a length between contacts on the patterned metallization layer between 20 µm and 100 µm.

16. The method according to claim 1, wherein the one or more airbridge structures have a width of more than 10 µm.

17. The method according to claim 1, wherein the one or more airbridge structures are formed using electroplating and have a width of more than 100 µm.

18. The method according to claim 1, wherein the electroplating for fabricating the 3D integration modules includes forming bumps made of a superconducting material to provide superconducting connections between bonded wafers.

19. A method for forming a quantum processor, comprising:
fabricating one or more airbridge structures and one or more 3D integration modules on a patterned metallization layer of a wafer comprising qubits or superconducting electronics, using a method according to claim 1; and
bonding the wafer to an additional wafer, comprising 3D integration modules, using the 3D integration modules of the wafer and the additional wafer to provide at least one of an electrical connection or a mechanical connection.

20. The method according to claim 19, wherein at least one of the one or more airbridge structures is configured to mitigate crosstalk and spurious modes in the quantum processor.
